(19) United States
(12) Patent Application Publication
(10) Pub. No.: US 2023/0290613 A1
(43) Pub. Date: Sep. 14, 2023

(54) SEMICONDUCTOR PROCESSING SYSTEM WITH GAS LINE FOR TRANSPORTING EXCITED SPECIES AND RELATED METHODS

(71) Applicant: ASM IP HOLDING B.V., Almere (NL)

(72) Inventors: Varun Sharma, Helsinki (FI); Tom Blomberg, Vantaa (FI)

(21) Appl. No.: 18/179,187

(22) Filed: Mar. 6, 2023

Related U.S. Application Data
(60) Provisional application No. 63/318,279, filed on Mar. 9, 2022.

(51) Int. Cl. H01J 37/32

(52) U.S. Cl. CPC H01J 37/32449; H01J 37/32816; H01J 37/32357; H01J 2237/182; H01J 2237/24585; H01J 2237/332

(57) ABSTRACT

A semiconductor processing system for providing a remotely generated excited species of a processing gas to a reactor. The semiconductor processing system comprises a remotely positioned plasma generator in fluid communication with a plasm source vessel and a gas line to convey an excited species generated in the plasma generator to the reactor. The gas line may be a double-walled pipe comprising an outer pipe and a perforated an inner pipe or a gas line to which DC bias voltage is applied.

### CROSS-REFERENCE TO RELATED APPLICATION

This Application claims the benefit of U.S. Provisional Application No. 63/318,279, filed Mar. 9, 2022.

### FIELD

This disclosure relates generally to a semiconductor processing system, and in particular a plasma processing system and method which provides a remotely-generated excited species to a reactor.

### BACKGROUND

In the field of semiconductor device fabrication, plasma processes are widely used. Plasma processing includes exposing a substrate to excited species, such as formed by plasma generation, to, for example, cause a reaction with or deposition on the substrate. Plasma processing may include, for example, plasma etching and plasma-enhanced deposition, such as plasma-enhanced chemical vapor deposition (CVD).

In a plasma processing apparatus for processing a substrate by exposure to excited species, a process gas is introduced into a reactor, or reaction chamber accommodating the substrate for processing. The excited species may be generated in situ or remotely. However, in situ plasma generation, in which excited species are generated in the reactor, may damage the material to be processed. Some applications, such as gate dielectric formation, are particularly sensitive to such damage. This damage may be repaired to some extent by an anneal, but the repair undesirably adds to the cost and, in addition, high temperatures during the annealing may increase the risk of oxidation.

Plasma damage due in situ plasma generation may be avoided by remotely generating the plasma. Remote plasma generation, however, has its own set of limitations, due, for example, to the need to transport excited species from the remote plasma generator to the reactor. Consequently, there is a need for improved systems and methods to convey excited species in remote plasma set up.

### SUMMARY

One object of one or more aspects of some embodiments is to provide a semiconductor processing system comprising hardware that may facilitate elongating the life span of excited species in remote plasma set ups and that may be utilized in various processes in the microelectronic industry, including surface treatments, reduction, oxidation, mitigating ion damage, deposition, and etching.

In some embodiments, a semiconductor processing system may comprise a plasma source vessel configured to contain plasma source gas and an inert gas source configured to provide inert gas. The system may further comprise a plasma generator in fluid communication with the plasma source vessel and a gas line to convey an excited species generated in the plasma generator to the reactor. The gas line may be a double-walled pipe, which may comprise an outer pipe and a perforated inner pipe.

In some other embodiments, a semiconductor processing system may comprise a plasma source vessel configured to contain plasma source gas. The system may further comprise a plasma generator in fluid communication with the plasm source vessel and configured to generate an excited species, a gas line to convey an excited species generated in the plasma generator to a reactor, and a voltage source configured to bias the gas line.

Another object of one or more aspects of some embodiments is to provide a semiconductor processing method for conveying excited species to a reactor of a semiconductor processing system from a remotely plasma generator.

In some embodiments, the method may comprise conveying the excited species generated in the remote plasma generator through the double-walled pipe, comprising an outer pipe and a perforated inner pipe, to the reactor.

In some other embodiments, the method may comprise conveying the excited species generated in the remote plasma generator through the electrically biased gas line to the reactor.

In yet other embodiments, the method may comprises conveying the excited species generated in the remotely set plasma generator through the double-walled pipe, comprising an outer pipe and a perforated inner pipe, to the reactor, while the voltage source biases the outer pipe.

Additional Examples:
1. A semiconductor processing system comprising:
   a plasma source vessel configured to contain a plasma source gas,
   an inert gas source configured to provide inert gas,
   a plasma generator in fluid communication with the plasma source vessel,
   a reactor, and
   a gas line to convey an excited species,
   wherein the reactor is in fluid communication with the plasma generator through the gas line, and
   wherein the gas line is a double-walled pipe.
2. The semiconductor processing system according to example 1, wherein the double-walled pipe comprises an outer pipe and a perforated inner pipe having a plurality of openings,
   wherein an inner surface of the outer pipe and an outer surface of the inner pipe define an outer volume therebetween, and
   wherein an inner surface of the inner pipe defines an inner volume within the inner pipe.
3. The semiconductor processing system according to example 2, wherein the double walled pipe comprises a first gas inlet in fluid communication with the outer volume and a second gas inlet in fluid communication with the inner volume,
   wherein the first gas inlet is configured to receive a first gas comprising the inert gas and the second gas inlet is configured to receive a second gas comprising the excited species.
4. The semiconductor processing system according to example 3 further comprising:
   a first pressure transducer configured to monitor a pressure within the outer volume,
   a second pressure transducer configured to monitor a pressure within the inner volume, and
   regulators to adjust a pressure difference between the pressure within the outer volume and the pressure within the inner volume.
5. The semiconductor processing system according to example 4, further comprising a control system configured to control operation of the regulators based at least in part on feedback of measured pressures in the outer volume and the inner volume.
6. The semiconductor processing system according to example 5, wherein the control system is configured to maintain a pressure of the first gas in the outer volume at a higher value than a pressure of the second gas in the inner volume.
7. The semiconductor processing system according to example 2, wherein an opening ratio of the inner pipe is from 10 to 80%.
8. The semiconductor processing system according to example 7, wherein the opening ratio of the inner pipe is progressively decreased toward the reactor.
9. The semiconductor processing system according to example 2, wherein a shape of the plurality of openings is circular.
10. The semiconductor processing system according to example 2, wherein the plurality of openings are defined by opening sidewalls extending obliquely to an axis of the inner pipe.
11. The semiconductor processing system according to example 2, wherein the outer pipe and the inner pipe are arranged concentrically and comprise an annular space therebetween.
12. The semiconductor processing system according to example 2, wherein the inner pipe comprises non-metallic material.
13. The semiconductor processing system according to example 11, wherein the inner pipe comprises polyvinyl chloride (PVC).
14. The semiconductor processing system according to example 3, wherein the first gas comprises a same gas as the second gas.
15. The semiconductor processing system according to example 3, wherein the semiconductor processing system is configured to provide the first gas and the second gas to a plenum of the reactor.
16. The semiconductor processing system according to example 3, wherein the double walled pipe comprises the first gas inlet on an outer surface of the outer pipe and the second gas inlet at an end of the inner pipe.
17. The semiconductor processing system according to example 1, further comprising a precursor vessel configured to contain a precursor, wherein the reactor is in fluid communication with the plasma generator through the gas line and the precursor vessel.
18. A semiconductor processing system comprising:
   a plasma source vessel configured to contain plasma source gas,
   a plasma generator in fluid communication with the plasma source vessel and configured to generate an excited species,
   a reactor,
   a gas line to convey the excited species, and
   a voltage source configured to bias the gas line,
   wherein the reactor is in fluid communication with the plasma generator through the gas line.
19. The semiconductor processing system according to example 18, wherein the voltage source is configured to provide DC bias voltage to the gas line.
20. The semiconductor processing system according to example 18, further comprising a control system to control a voltage and a polarity of the bias.
21. The semiconductor processing system according to example 18, wherein the control system is configured to control a polarity of the bias of the gas line to match a polarity of the excited species generated by the plasma generator.
22. The semiconductor processing system according to example 18, further comprising a precursor vessel configured to contain precursor, wherein the reactor is in fluid communication with the precursor vessel.
23. The semiconductor processing system according to example 18, wherein the gas line is a double-walled pipe comprising an inner pipe inside an outer pipe, wherein the outer pipe is configured to be biased by the voltage source.
24. The semiconductor processing system according to example 23, wherein the voltage source is configured to provide DC bias voltage to the gas line.
25. A method for semiconductor processing comprising;
   providing excited species to a reactor of a semiconductor processing system through a double-walled pipe comprising an outer pipe and an inner pipe defining an outer volume therebetween, the inner pipe disposed within the outer pipe and having an interior volume and a plurality of openings, wherein providing the excited species comprises:
      flowing a plasma source gas to a plasma generator,
      activating the plasma source gas to form an excited plasma source gas,
      flowing the first gas to the outer volume of the double-walled pipe,
      flowing the excited plasma source gas to the interior volume of the inner pipe, and
      conveying the excited plasma source gas through the double-walled pipe to the reactor.
26. The method according to example 25, wherein a pressure of the first gas within the outer volume is higher than a pressure of the excited plasma source gas within the interior volume.
27. The method according to example 25, wherein the first gas comprises a same gas species as the excited plasma source gas.
28. The method according to example 25, further comprising maintaining a pressure difference between the outer volume and the interior volume, wherein the pressure difference is 1 Torr or more.
29. A method for semiconductor processing comprising;
   providing excited species to a reactor of a semiconductor processing system through a gas line, wherein providing the excited species comprises:
   providing a plasma source gas to a plasma generator,
   exciting the plasma source gas to form the excited species,
   applying a bias voltage to the gas line,
   providing the excited species to the gas line,
   conveying the excited species through the gas line to the reactor.
30. The method according to example 29, wherein the bias voltage is DC bias voltage.
31. The method according to example 29, wherein a polarity of the bias is a same as a polarity of ions in the excited species.
32. The method according to example 29, further comprising applying a bias voltage to the outer pipe.
33. The method according to example 32, wherein the bias voltage is DC bias voltage.
34. The method according to example 33, wherein applying a bias voltage to the gas line and providing the excited species to the gas line forms exited species in the gas line.

### BRIEF DESCRIPTION OF THE DRAWINGS

The foregoing and other objectives and advantages will appear from the description herein. In the description reference is made to the accompanying drawing, which forms a part hereof, and in which is shown by way of illustration specific embodiments. These embodiments will be described in sufficient detail to enable those skilled in the art to practice the embodiments, and it is to be understood that other embodiment may be utilized and that structural changes may be made without departing from the scope of the disclosed embodiments. The accompanying drawing, therefore, is submitted merely as showing examples of the disclosed embodiments. Accordingly, the following detailed description is not to be taken in a limiting sense, and the scope of the present disclosed embodiments is defined by the appended claims

FIG. 1 is a schematic diagram of a semiconductor processing system configured to convey an excited species in a gas to a reactor through a double-walled pipe in accordance with some embodiments.

FIG. 2 illustrates a double-walled pipe in accordance with various embodiments.

FIG. 3 is a schematic diagram of a semiconductor processing system configured to convey an excited species in a gas to a reactor through a gas pipe biased by a voltage source in accordance with some embodiments.

FIG. 4 is a schematic diagram of a semiconductor processing system configured to convey an excited species in a gas to a reactor through a double-walled pipe biased by a voltage source in accordance with some embodiments.

FIG. 5 is a flow chart showing a method for conveying an excited species to a reactor through a double-walled pipe in accordance with some embodiments.

FIG. 6 is a flow chart showing a method for conveying an excited species to a reactor through a gas line biased by a voltage source in accordance with some embodiments.

FIG. 7 is a flow chart showing a method for conveying an excited species to a reactor through a double-walled pipe biased by a voltage source in accordance with some embodiments.

### DETAILED DESCRIPTION

In semiconductor processing systems with remote plasma generation, it will be appreciated that loss of excited species may occur during transport of the excited species. Without being limited by theory, it is believed that this loss may be caused by, for example, collision of the excited species with the gas line used to convey the plasma (and the occurrence of collisions may be intensified where the flow dynamics causes recirculation of excited species before the excited species reach the substrate) and/or with other species in the gas flow, and/or due to recombination with other excited species.

In addition, the relatively low temperature of the reaction chamber may also cause excited species loss as the energy of the excited species decreases. Moreover, near the substrate, there may be competitive effects in which the hot susceptor area provides additional energy to reduce excited species loss, but the presence of the excited species in this volume may increase the occurrence of collisions and lead to further excited species loss.

In some embodiments, the loss of excited species is mitigated using a gas-line to transport the excited species from a remote plasma generator to the reaction chamber of a reactor. The gas line may be formed by a pipe that is enclosed within another pipe, thereby forming two volumes (for example, two concentric volumes—an inner volume and an annular outer volume) for conveying gas from the remote plasma generator to the reaction chamber. In some embodiments, the inner pipe may be perforated, to allowing gas from the outer volume (between the inner pipe and the outer pipe) to flow into the inner volume of the inner pipe. This gas flow creates a gas cushion that prevents the excited species from colliding with the gas line. In some other embodiments, in addition to or as an alternative to the gas cushion, the gas line may be electrically biased, for example, to provide a charge-based repulsion of the excited species from the walls of the gas line. The gas line to be electrically biased may be electrically isolated from the semiconductor processing systems with the help of insulating material; for example, electrically insulating material may be placed between the gas line and conductive parts of the semiconductor process system. Advantageously, by preventing collisions between the excited species and the walls of the gas line, the lifespan of active species from the remote plasma generator may be extended, thereby improving process results within the reaction chamber. Preferably, the gas pressure within the inner volume for transporting the excited species is also sufficiently low to maintain collisions between excited species molecules at a low level.

Hereafter an apparatus and a method will be described in detail by way of embodiments shown in the attached drawings. Like numerals refer to like parts throughout.

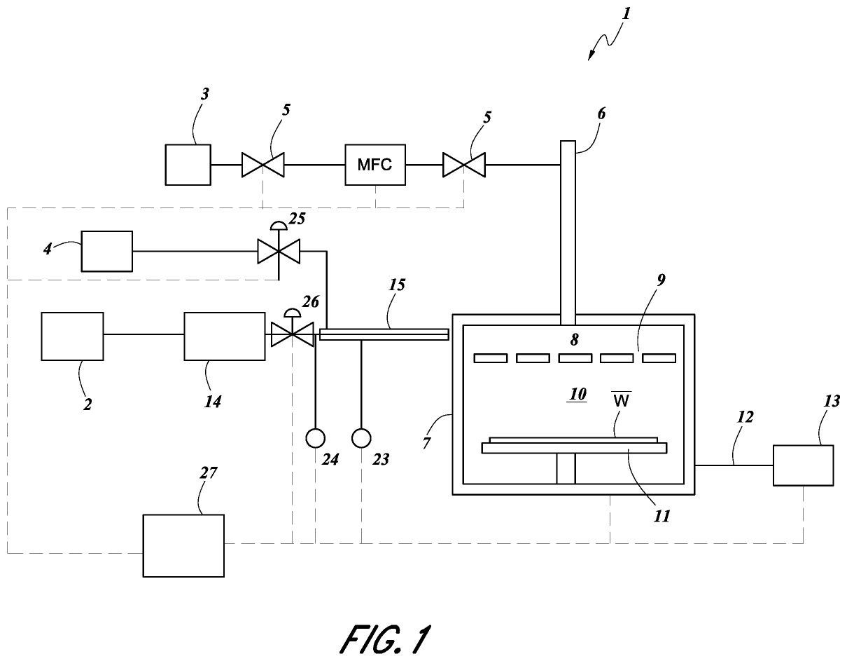

FIG. 1 is a schematic system diagram of a semiconductor processing system 1, according to various embodiments. The system 1 may include a plasma source vessel 2 configured to contain plasma source gas, an inert gas source 4 configured to provide inert gas, and a reactor 7, which has a reaction chamber 11 for processing substrates, such as semiconductor wafers W. Between the plasma source vessel 2 and the reactor 7, the system 1 may further include a remote plasma generator 14 in fluid communication with the plasma source vessel 2 and a gas line 15 to convey an excited species generated in the plasma generator 14 to the reactor 7. The remote plasma generator 14 may be configured to provide a sufficiently large amount of energy to the plasma source gas to generate the excited species, which may include radicals or activated or ion species. In some embodiments, the remote plasma generator 14 may generate a plasma therein. As noted above, it will be appreciated that the system diagram of FIG. 1 is schematic and the physical positions of various system components may vary in practice. For example, the remote plasma generator 14 may be positioned directly above the shower head plenum 8 in some applications.

In some embodiments, the inert gas source 4 may be a vessel containing an inert gas therein. In some embodiments, the plasma source vessel 2 may hold a gas which may be flowed to the remote plasma generator 14 to be activated, or excited, to form an excited species which is subsequently flowed to the reactor 7.

It will be appreciated that the remote plasma generator 14 is remote in the sense that it forms excited species outside of the reaction chamber 10. Previously, remote plasma generators have been located close to the entrance to a reaction chamber, to prevent the loss of excited species as the excited species travel from the remote plasma generator to the reaction chamber. As discussed herein, various embodiments advantageously preserve excited species conveyed through the gas line 15 between the remote plasma generator 14 and the reactor 7. As a result, greater flexibility for the location of the remote plasma generator 14 may be provided. For example, since the remote plasma generators 14 are no longer required to be confined to locations close to (e.g., on top of) the reaction chamber 10, exceptionally large remote plasma generators 14 may be utilized in some embodiments. The plasma generator 14 may include a pair of electrodes which are capacitively coupled and are activated by applying AC power. In some embodiments, the remote plasma generators 14 may be operated from about 2 MHz to 120 MHz, preferably from 10 MHz to about 60 MHz, more preferably 13.56 MHz, and or 27 MHz, or 40 MHz and or 60 MHz. In some embodiments, the remote plasma generators 14 may be operated from about 5 W to about 10 kW, preferably 50 W to about 5 kW, more preferably about from 100 W to about 1 kW. In some embodiments, the remote plasma generators 14, can be of exceptionally powerful and of large sizes such as weighing more than few hundred kilo grams, and utilizing power more than 1 kW.

While only one plasma generator 14 is illustrated in FIG. 1, it should be appreciated that in some other embodiments, more than one plasma generator 14 may be utilized. For example, one or more other remote plasma generators may be in fluid communication with one or more other respective plasma source vessels, which may in turn be in fluid communication with the reactor 7 through associated gas lines similar to the gas line 15.

With continued reference to FIG. 1, in some embodiments, the gas line 15 may convey an excited species generated in the remote plasma generator 14, along with the inert gas provided from the inert gas source 4, to the reaction chamber 10 of the reactor 7. A dispersion device, such as a shower head having a plenum 8 in fluid communication with openings 9, may be provided in the reactor 7. The excited species may pass through the openings 9 and be supplied into the reaction chamber 10 to be applied to the substrate, for example the semiconductor wafer W. The wafer W may be supported on a substrate support 11 within the reaction chamber 10.

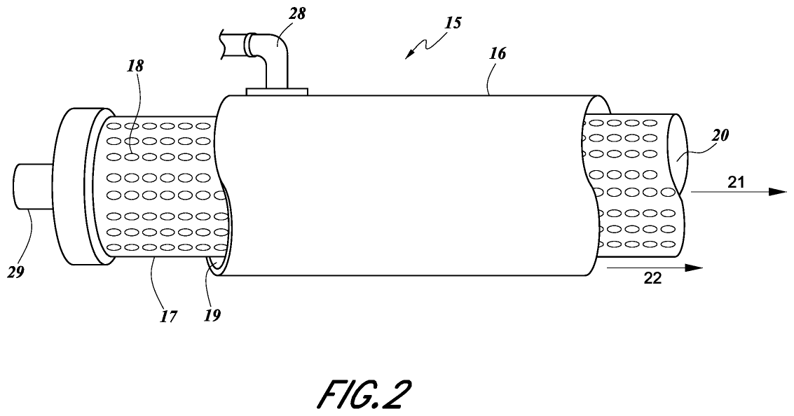

As shown in a FIG. 2, the gas line 15 may be a double-walled pipe. The double-walled pipe may include an outer pipe 16 and an inner pipe 17. The outer pipe 16 and the inner pipe 17 may be formed of metallic material in some embodiments. In some other embodiments, one or both of the outer pipe 16 and the inner pipe 17 may be formed of non-metallic material, such as an insulator, such as polyvinyl chloride (PVC). In some embodiments, the outer pipe 16 may be formed of a metal and the inner pipe 17 may be formed of an insulator. In some embodiments, the outer pipe 16 and or the inner pipe 17 may be formed of a metal and coated with insulating layers such as aluminum oxide, polymer, and any other electrical insulator etc. In some embodiments, the outer pipe 16 and the inner pipe 17 may be arranged concentrically and may include an annular space therebetween. In some other embodiments, the position of the inner pipe 17 may be skewed such that there is a larger gap between the inner pipe 17 and the outer pipe 16 on one side of the inner pipe 17 than the opposite side of the inner pipe 17. Preferably, for ease of manufacture and compatibility with other equipment, the outer pipe 16 and the inner pipe 17 may have circular cross-sections (as viewed on a plane transverse to a length axis of the pipes 16 and 17.

With continued reference to FIG. 2, an inner surface of the outer pipe 16 and an outer surface of the inner pipe 17 may define an outer volume 19 therebetween. An inner surface of the inner pipe 17 defines an inner volume 20 within the inner pipe 17. The inner pipe 17 is preferably perforated and has a plurality of openings 18. A shape of the plurality of openings 18 may be circular to facilitate their formation (e.g., by drilling into the inner pipe 17). In some embodiments, the openings 18 may have other cross-sectional shapes, for example, oval, rectangular, etc. In some embodiments, the openings 18 may have a uniform size and/or shape. In some embodiments, one or both of the size and shape of the openings 18 may vary. As discussed herein, the size, shape, and distribution of the openings 18 is preferably selected to output gas into the inner volume 20 to form a gas curtain which reduces contact between excited species in the inner volume 20 and the inner pipe 17.

In some embodiments, the size of each opening and the number of the openings 18 may be determined based on an opening ratio. The opening ratio is the amount of open area per unit area, in the form of a percentage relative for the unit area. The opening ratio of the inner pipe 17 may be from 1 to 80%. In some embodiments, the opening ratio of the inner pipe 17 may be from 5 to 50%, preferably from 10 to about 30%, more preferably less than about 25%. The opening ratio of the inner pipe 17 may be constant throughout entire length of the gas line 15 or may vary. In some embodiments, the opening ratio may decrease from the remote plasma generator 14 toward the reactor 7 (FIG. 1). For example, the opening ratio at an end of the gas line 15 where the plasma generator is coupled may be about 50%, while at an end where the reactor 7 is coupled to the gas line 15, the opening ratio may be 30%. In some embodiments, the opening ratio therebetween may be progressively decreased toward the reactor 7. In some embodiments, the opening ratio there between may progressively increase toward the reactor 7. For example, the opening ratio at an end of the gas line 15 where the plasma generator is coupled may be about 30%, while at an end where the reactor 7 is coupled to the gas line 15, the opening ratio may be about 70%.

In some embodiments, the openings 18 may extend through the inner pipe 17 parallel to the normal to the outer surface of the inner pipe 17, and may be oriented perpendicular to the elongate axis of the inner pipe 17. In some other embodiments, the openings 18 may be slanted, such that they extend through the inner pipe 17 at an angle offset from the normal to the outer surface of the inner pipe 17; stated another way, they may extend obliquely to the elongate axis of the inner pipe 17. In some embodiments, the openings 18 may be slanted such that they extend into the inner pipe 17 generally going with the direction of gas flow from the plasma generator 14 to the reactor 7 (FIG. 1). As a result, gas from the outer volume 19 continues to flow “forward” toward the reactor 7 as it moves through an opening 18. Such an angle may help to capture gas from the outer volume 19 and facilitate formation of the desired gas curtain in the inner pipe 17. In some embodiments, the angle of the slant of the openings 18 may vary from the end of the gas line 15 proximate the remote plasma generator 14 to end proximate the reactor 7. For example, in addition to or as an alternative to decreasing the opening ratio from the remote plasma generator 14 to the reactor 7, the angle of the slant of the openings 18 may change from the end of the inner pipe 17 proximate the remote plasma generator 14 to the end proximate the reactor 7. For example, the openings 18 may initially be slanted generally in the direction of the gas flow and the angle may change such that it is substantially normal to the outer surface of the inner pipe 17, or the angle may further progress such that the openings 18 are slanted against the direction of the gas flow. Advantageously, the manipulation of the angles at which the openings 18 are slanted allows a degree of control over the quantity and flow rate of gas entering the inner volume 20 from the outer volume 19, which can further provide control over the gas curtain formed by that gas flow. In some embodiments, slanting the openings 18 in the general direction of the gas flow may allow more gas to be captured and flowed into the inner volume 20 than otherwise available with similar sized openings 18.

With continued reference to FIG. 2, the double walled pipe 15 may include a first gas inlet 28 on an outer surface of the outer pipe 16 and a second gas inlet 29 at an end of the inner pipe 17 proximate the remote plasma generator 14 (FIG. 1). As a result, the first gas inlet 28 is in fluid communication with the outer volume 19 and the second gas inlet 29 is in fluid communication with the inner volume 20. Preferably, the inert gas source 4 provides inert gas to the outer volume 19 through the first gas inlet 28 as the first gas 21, and the remote plasma generator 14 provides excited species to the inner volume 20 through the second gas inlet 29 as the second gas 22. As discussed herein, the first gas 21 may be provided to the first gas inlet 28 to create a gas curtain that prevents collision of the excited species with surfaces of the pipe 15, particularly the inner wall surfaces of the inner pipe 17. Examples of the first gas and the second gas are listed in Table 1. Preferably, as discussed herein, the first gas 21 may include an inert gas and the second gas 22 may include the excited species (e.g., in combination with an inert carrier gas).

TABLE 1

| First Gas | Second Gas |
|---|---|
| H₂ | H₂ plasma |
| Ar | Ar plasma |
| N₂ | N₂ plasma |
| NH₃ | NH₃ plasma |

In some embodiments, the first gas 21 may include the same chemical element as the excited species of the second gas 22. For example, where the second gas 22 includes H₂ plasma, the first gas 21 may include H₂ gas. Advantageously, without being limited by theory, such use of similar chemical elements in the first and second gases 21 and 22 is believed to help reduce the occurrence of recombination of the excited species in the first gas 21, to improve excited species life duration. In some other embodiments, different chemical elements may be used for the first and second gases 21 and 22, for example, respectively, Ar with H₂ plasma or N₂ plasma. In some embodiments, halide gases may be part of the second gas 22 and plasma may be generated with these halide gases for various applications such as etching, selective deposition and surface modifications etc. Examples of halides gases include diatomic halide gases such as Cl₂, F₂, and Br₂; hydrogen halides, e.g., HCl, HBr, HF, HI; and other halides, e.g., CF₄, C₂F₆, SF₆, SF₆. The pipe 15 may be configured to provide the first gas 21 and the second gas 22 to the plenum 8 of the reactor 7.

With continued reference to FIG. 2, the semiconductor processing system 1 may include a first pressure transducer 23 (FIG. 1) configured to monitor a pressure within the outer volume 19 and a second pressure transducer 24 (FIG. 1) configured to monitor a pressure within the inner volume 20. The pressure transducers 23, 24 may likewise include a high temperature-compatible sensor, such as a capacitance manometer pressure transducer. A pressure difference between the pressure within the outer volume 19 and the pressure within the inner volume 20 may be adjusted by regulators 25, 26 (optional) based on the measured pressure by the transducers 23, 24. Adjusting the pressure difference may further provide room for tuning properties of a film deposited on the wafer W, in conjunction with reducing the loss of excited species due to collisions with surfaces of the pipe 15. In some embodiments, the pressure difference may be 10 Torr or more, preferably in a range of 10 Tor-1000 Torr, preferably from 50 Torr to 500 Torr. or more preferably from 100 Torr to 300 Torr. In some embodiments, the pressure difference may be less than about 500 Torr, or less than about 300 Torr, or more preferably less than about 200 Torr. In some embodiments, the pressure difference may be less than about 10 Torr, or less than about 1 Torr. or more preferably less than about 0.5 Torr.

With reference again to FIG. 1, the semiconductor processing system 1 may further include a control system 27 configured to control the operation of various components of the system 1, such as the regulators 25, 26, valves 5, the pressure transducer 23, 24, the reactor 7 (and the various components therein), and the vacuum pump 13. In some embodiments, the control system 27 may control operation of the regulators 25, 26 based at least in part on feedback of measured pressures in the outer volume 19 and the inner volume 20, to maintain the pressure of the first gas 21 in the outer volume 19 at a higher value than the pressure of the second gas 22 in the inner volume 20. In some embodiments, the regulators 25, 26 may be omitted from the semiconductor processing system 1.

The control system 27 includes one or more processors, memory devices, and other electronic components that control the operation of various components of the system 1. As used herein, the term “control system” includes any combination of individual controller devices and processing electronics that may be integrated with or connected to other devices (such as valves, sensors, etc.). Thus, in some embodiments, the control system 27 may include a centralized controller that controls the operation of multiple (or all) system components. In some embodiments, the control system 27 may include a plurality of distributed controllers that control the operation of one or more system components. Control sequences may be hardwired or programmed into the control system 27. The memory devices of the control system 27 include non-transitory computer-readable medium, such as physical computer storage including hard drives, solid state memory, random access memory (RAM), read only memory (ROM), optical disc, volatile or non-volatile storage, combinations of the same and/or the like. The non-transitory computer-readable medium provides instructions to the one or more processors. It will be appreciated that the instructions may be for any of the actions described herein, such that processing of the instructions by the one or more processors causes the system 1 to perform those actions.

The semiconductor processing system may further include a precursor vessel 3 configured to contain a precursor which is a different species from the plasma source provided by the plasma source vessel 2. The reactor 7 may be in fluid communication with the plasma generator 14 through the gas line 15 and the precursor vessel 3 through a manifold 6. In some embodiments, excited species from the plasma source vessel 2 and precursor from the precursor vessel 3 may react to form a compound film on the wafer W. A vapor-phase precursor from the precursor vessel 3 may be provided through a flow controller (MFC) and valves 5, as shown in FIG. 1. Although only one precursor vessel 3 is shown in FIG. 1, it should be appreciated that in other embodiments, more than a single precursor vessel 3 may be coupled to the reactor 7. In some embodiments, the reactor 7 may only be used for plasma treatment of the wafer W, and the precursor vessels 3 may be omitted from the system 1.

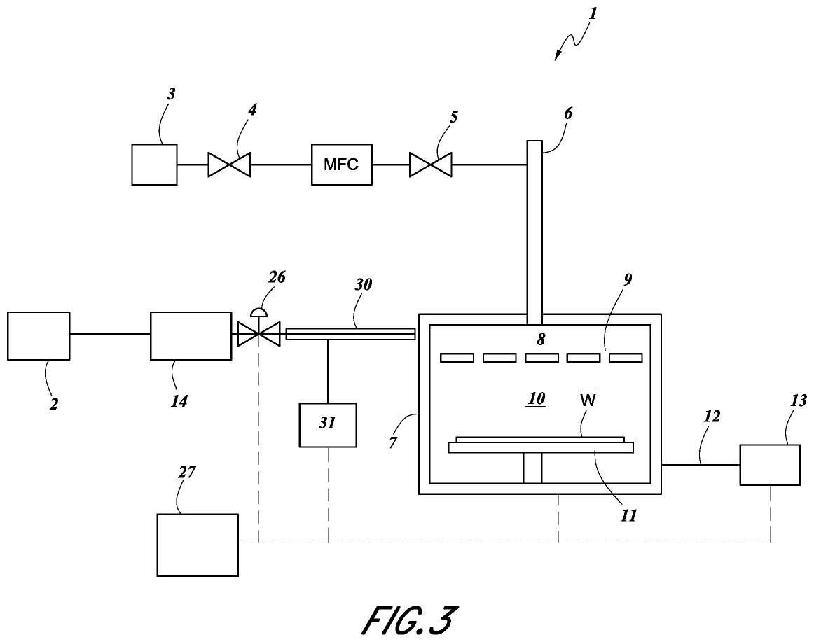

In some embodiments, semiconductor processing system 1 may have a gas line 30 which is biased by an applied potential from a voltage source, with the biasing configured to repel, or attract, excited species from walls of the gas line 30. FIG. 3 is a schematic system diagram of a semiconductor processing system 1 having the gas line 30, according to a various embodiments. The system 1 may include a plasma source vessel 2 configured to contain a plasma source gas, a remote plasma generator 14, and a reactor 7. The gas line 30 may be in fluid communication with the plasma generator 14 and the reactor 7, and may convey an excited species generated in the plasma generator 14 to a reaction chamber 10 of the reactor 7. The reactor 7 may have a dispersion device, such as a shower head, which may have a plenum 8 in a fluid communication with openings 9. Excited species may pass through the openings 9 and to enter the reaction chamber 10 and be applied to the wafer W, which is supported on a substrate support 11 within the reaction chamber 10.

With continued reference to FIG. 3, the voltage source 31 may be configured to provide a DC bias voltage to the gas line 30. In some embodiments, the voltage source 31 may include one or more batteries, fuel cells, capacitors, generators, or rectifiers (which may be configured to convert alternating current that is obtained from an AC power grid to direct current). The semiconductor processing system 1 may further include a control system 27 configured to control, among other things, a magnitude and a polarity of the bias to be applied to the gas line 30. The bias voltage may be in range of 10 V-10 kV, preferably 50 V-600 V, more preferably 100 V-500 V. In some embodiments, the polarity of the bias may be the same as the polarity of ions in the excited species that is generated by the plasma generator. The biasing may cause the biased surface of the gas line 30 to deflect the active species from the gas line surface and may help to prevent recombination of active species. In some embodiments, the biasing may assist in creating new excited species or to filter ions. For example, ions having the same polarity as the biased gas line surfaces may be repelled from those surfaces and continue on to the reactor 7, while ions of an opposite polarity may be attracted to the gas line surfaces and prevented from flowing to the reactor 7.

As shown in FIG. 3, as discussed with reference to FIG. 1, the system may further include a precursor vessel 3 configured to contain precursor 3 which is a different species from the plasma source. The reactor 7 may be in fluid communication with the plasma generator 14 through the gas line 30 and with the precursor vessel 3 through a manifold 6, thereby allowing formation of a compound film on the wafer W in some embodiments. A vapor-phase precursor from the precursor vessel 3 is provided through a flow controller (MFC) and valves 5.

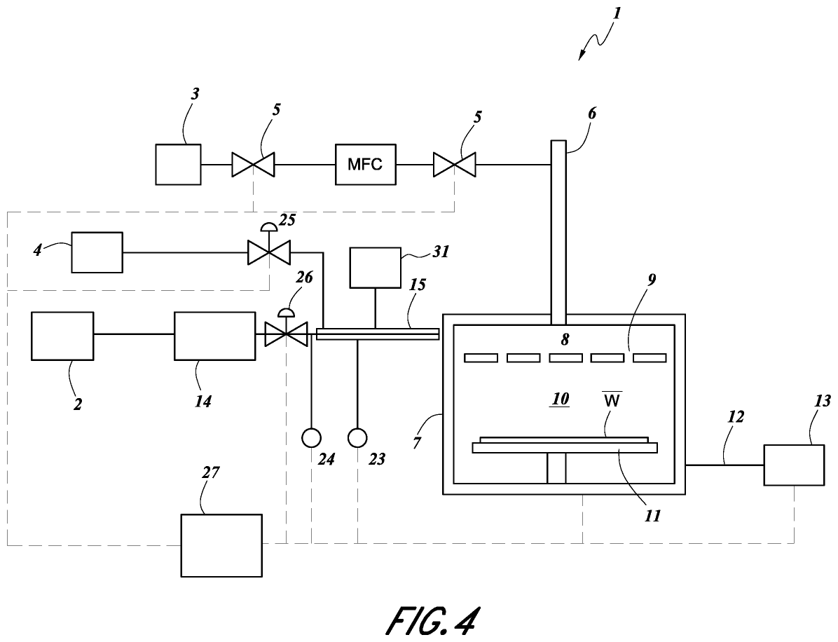

In some embodiments, the double-walled gas line 15 of the semiconductor processing system 1 may be biased. With reference now to FIG. 4, the outer pipe 16 and/or the inner pipe 17 of the double-walled gas line 15 may be biased using the voltage source 31 as described above. For example, the gas line 15 may be biased as discussed above for gas line 30 to achieve similar results. In some embodiments, along with the gas curtain created by the first gas 21 (FIG. 2), a bias voltage applied to the outer pipe 16, and having the same polarity as desired excited species flowing through the gas line 15, may be used to deflect the excited species from surfaces of the gas line 15 and thereby prevent collision with those surfaces.

In some embodiments, both the outer pipe 16 and the inner pipe 17 may be biased to generate excited species inside the gas line 15. For example, the outer pipe 16 and the inner pipe 17, respectively, may be provided with opposite bias. In some embodiments, the bias of the inner pipe 17 and the outer pipe 16 is adjusted to maintain certain voltage differences. In some embodiments. RF (Radio Frequency) bias can be applied to the inner pipe, and/or the outer pipe separately.

It will be appreciated that the present disclosure also relates to methods for transporting, or conveying, excited species to a reactor 7 of a semiconductor processing system 1 through the double-walled gas line 15, and methods for conveying excited species to a reactor 7 of a semiconductor processing system 1 through the gas line 30 (FIG. 3) or the gas line 15 (FIG. 4), to which DC bias voltage is applied.

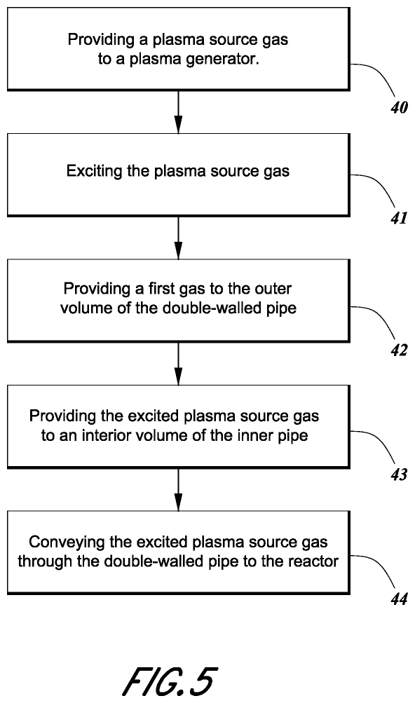

FIG. 5 is a flow chart generally illustrating a method for conveying excited species to a reactor 7 (FIG. 1) of a semiconductor processing system 1 through a double-walled pipe 15 including an outer pipe 16 and an inner pipe 17 defining an outer volume 19 therebetween, the inner pipe having a plurality of openings 18 and disposed within the outer pipe. At block 40, a plasma source gas is provided to the plasma generator 14 and the plasma source gas is excited at block 41. At block 42, the first gas 21, which is an inert gas, is provided to the outer volume 19. At block 43, the excited plasma source gas is provided to an inner volume 20 of the inner pipe 17. At block 44, the excited plasma source gas (the second gas 22) is conveyed to the reactor 7 through the double walled pipe 15. The semiconductor processing system 1 may be configured to provide the first gas 21 and the second gas 22 to the plenum 8 of the reactor 7. As indicated in Table 1, in some embodiments, the first gas 21 may include the same element as the second gas 22. For example, where H₂ plasma is part of the second gas 22, using H₂ gas as the first gas 21 may prevent recombination. Similar atoms may improve excited species life. Nevertheless, in some embodiments, different atoms may be used, for example Ar with H₂ plasma or N₂ plasma. Moreover, the pressure of the first gas 21 within the outer volume 19 may be higher than the pressure of the excited plasma source gas (the second gas 22) within the interior volume 20.

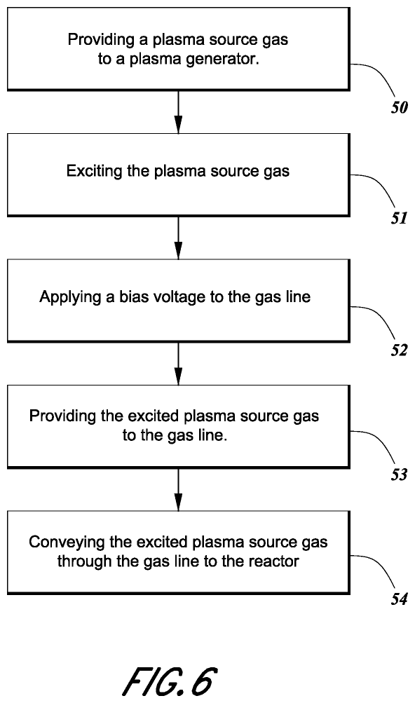

FIG. 6 is a flow chart generally illustrating a method for conveying excited species to a reactor 7 of a semiconductor processing system 1 through a biased gas line 30 (FIG. 3). At block 50, a plasma source gas is provided to the plasma generator 14 and the plasma source gas is excited at block 51. At block 52, a bias voltage is applied to the gas line 30. In some embodiments, the bias voltage may be a DC bias voltage, with a polarity of the bias may be same as a polarity of ions in the excited species which are desired to be transported to the reactor 7. At block 53, the excited plasma source gas is provided to the biased gas line 30 and the excited plasma source gas is conveyed to the reactor 7.

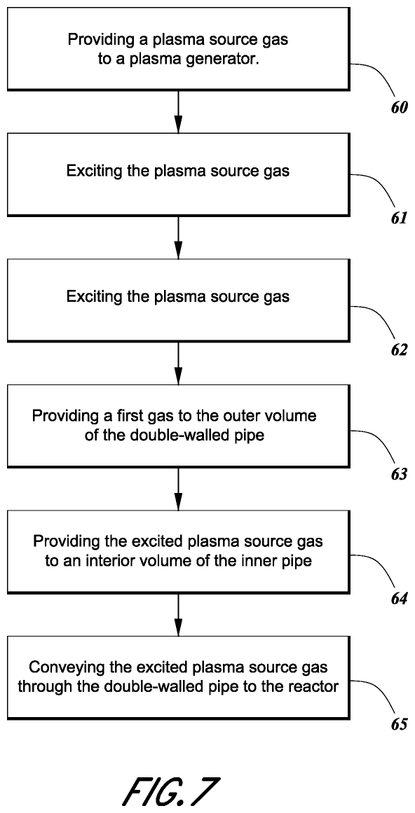

As also shown in FIG. 7, the bias voltage may be applied to the double-walled pipe 15, such as, for example, the outer pipe 16 of the double-walled pipe 15. At block 60, a plasma source gas is provided to the plasma generator 14 and the plasma source gas is excited at block 61. At block 62, a bias voltage is applied to the double-walled pipe 15. The bias voltage may be DC bias voltage and a polarity of the bias may be the same as a polarity of ions in the excited species which are desired to be transported to the reactor 7. At block 63, the first gas 21, which is an inert gas, is provided to the outer volume 19 of the double walled pipe 15. At block 64, the excited plasma source gas is provided to the inner volume 20 of the inner pipe 17. At block 65, the excited plasma source gas (the second gas 22) is conveyed to the reactor 7 through the double-walled pipe 15.

For purposes of this disclosure, certain aspects, advantages, and novel features are described herein. Not necessarily all such advantages may be achieved in accordance with any particular embodiment. Thus, for example, those skilled in the art will recognize that the disclosure may be embodied or carried out in a manner that achieves one advantage or a group of advantages as taught herein without necessarily achieving other advantages as may be taught or suggested herein.

For example, it will be appreciated that the reaction chamber 10 may be a single substrate chamber, designed to accommodate a single substrate. In some other embodiments, the reaction chamber may be a batch reaction chamber, which simultaneously accommodates and processes a plurality of substrates. Also, the multi-walled pipe 15 is preferably double-walled, but, in some embodiments, may include three or more pipes all of which may be concentric. In some embodiments, the voltage source 31 may be a current source configured to provide current to the pipe 15 or pipe 30.

Conditional language, such as “may”, “can,” “could,” “might,” or “may,” unless specifically stated otherwise, or otherwise understood within the context as used, is generally intended to convey that certain embodiments include, while other embodiments do not include, certain features, elements, and/or steps. Thus, such conditional language is not generally intended to imply that features, elements, and/or steps are in any way required for one or more embodiments or that one or more embodiments necessarily include logic for deciding, with or without user input or prompting, whether these features, elements, and/or steps are included or are to be performed in any particular embodiment.

Language of degree used herein, such as the terms “approximately,” “about,” “generally,” and “substantially” as used herein represent a value, amount, or characteristic close to the stated value, amount, or characteristic that still performs a desired function or achieves a desired result. For example, the terms “approximately”, “about”, “generally,” and “substantially” may refer to an amount that is within less than 10% of, within less than 5% of, within less than 1% of, within less than 0.1% of, and within less than 0.01% of the stated amount.

The scope of the present disclosure is not intended to be limited by the specific disclosures of preferred embodiments in this section or elsewhere in this specification, and may be defined by claims as presented in this section or elsewhere in this specification or as presented in the future. The language of the claims is to be interpreted based on the language employed in the claims and not limited to the examples described in the present specification or during the prosecution of the application, which examples are to be construed as non-exclusive.

What is claimed is:

1. A semiconductor processing system comprising:
a plasma source vessel configured to contain a plasma source gas,
an inert gas source configured to provide inert gas,
a plasma generator in fluid communication with the plasma source vessel,
a reactor, and
a gas line to convey an excited species,
wherein the reactor is in fluid communication with the plasma generator through the gas line, and
wherein the gas line is a double-walled pipe.

2. The semiconductor processing system according to claim 1, wherein the double-walled pipe comprises an outer pipe and a perforated inner pipe having a plurality of openings,
wherein an inner surface of the outer pipe and an outer surface of the inner pipe define an outer volume therebetween, and
wherein an inner surface of the inner pipe defines an inner volume within the inner pipe.

3. The semiconductor processing system according to claim 2, wherein the double walled pipe comprises a first gas inlet in fluid communication with the outer volume and a second gas inlet in fluid communication with the inner volume,
wherein the first gas inlet is configured to receive a first gas comprising the inert gas and the second gas inlet is configured to receive a second gas comprising the excited species.

4. The semiconductor processing system according to claim 3 further comprising:
a first pressure transducer configured to monitor a pressure within the outer volume,
a second pressure transducer configured to monitor a pressure within the inner volume, and
regulators to adjust a pressure difference between the pressure within the outer volume and the pressure within the inner volume.

5. The semiconductor processing system according to claim 4, further comprising a control system configured to control operation of the regulators based at least in part on feedback of measured pressures in the outer volume and the inner volume.

6. The semiconductor processing system according to claim 5, wherein the control system is configured to maintain a pressure of the first gas in the outer volume at a higher value than a pressure of the second gas in the inner volume.

7. The semiconductor processing system according to claim 2, wherein an opening ratio of the inner pipe is from 10 to 80%.

8. The semiconductor processing system according to claim 7, wherein the opening ratio of the inner pipe is progressively decreased toward the reactor.

9. The semiconductor processing system according to claim 2, wherein the plurality of openings are defined by opening sidewalls extending obliquely to an axis of the inner pipe.

10. The semiconductor processing system according to claim 2, wherein the outer pipe and the inner pipe are arranged concentrically and comprise an annular space therebetween.

11. The semiconductor processing system according to claim 2, wherein the inner pipe comprises non-metallic material.

12. The semiconductor processing system according to claim 3, wherein the first gas comprises a same gas as the second gas.

13. The semiconductor processing system according to claim 3, wherein the semiconductor processing system is configured to provide the first gas and the second gas to a plenum of the reactor.

14. The semiconductor processing system according to claim 3, wherein the double walled pipe comprises the first gas inlet on an outer surface of the outer pipe and the second gas inlet at an end of the inner pipe.

15. The semiconductor processing system according to claim 1, further comprising a precursor vessel configured to contain a precursor, wherein the reactor is in fluid communication with the plasma generator through the gas line and the precursor vessel.

16. A semiconductor processing system comprising:
a plasma source vessel configured to contain plasma source gas,
a plasma generator in fluid communication with the plasma source vessel and configured to generate an excited species,
a reactor,
a gas line to convey the excited species, and
a voltage source configured to bias the gas line,
wherein the reactor is in fluid communication with the plasma generator through the gas line.

17. The semiconductor processing system according to claim 16, wherein the voltage source is configured to provide DC bias voltage to the gas line.

18. The semiconductor processing system according to claim 16, further comprising a control system to control a voltage and a polarity of the bias.

19. The semiconductor processing system according to claim 16, wherein the control system is configured to control a polarity of the bias of the gas line to match a polarity of the excited species generated by the plasma generator.

20. The semiconductor processing system according to claim 16, further comprising a precursor vessel configured to contain precursor, wherein the reactor is in fluid communication with the precursor vessel.

21. The semiconductor processing system according to claim 16, wherein the gas line is a double-walled pipe comprising an inner pipe inside an outer pipe, wherein the outer pipe is configured to be biased by the voltage source.

22. The semiconductor processing system according to claim 21, wherein the voltage source is configured to provide DC bias voltage to the gas line.
